(19) United States
(12) Patent Application Publication
(10) Pub. No.: US 2026/0271805 A1
(43) Pub. Date: Sep. 10, 2026

(54) CHIP-STACKED DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Yoshiaki SHIMOOKA, Sagamihara Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/542,754

(22) Filed: Feb. 18, 2026

(30) Foreign Application Priority Data
Mar. 10, 2025 (JP) 2025-037662

(51) Int. Cl. H10W 90/00; H10W 90/28

(52) U.S. Cl. CPC H10W 90/732; H10W 90/28

(57) ABSTRACT

A chip-stacked device includes: a first chip including a first substrate, the first substrate including a first outer peripheral region and a first array region surrounded by the first outer peripheral region; a second chip including a second substrate, the second substrate including a second outer peripheral region and a second array region, the second outer peripheral region facing the first outer peripheral region, the second array region being surrounded by the second outer peripheral region and facing the first array region; and a plurality of bonding members provided between the first array region and the second array region to bond the first chip and the second chip. A thickness of the second outer peripheral region of the second substrate is thicker than a thickness of the second array region of the second substrate.

### CROSS-REFERENCE TO RELATED APPLICATION

This application is based upon and claims the benefit of priority from Japanese Patent Application No. 2025-037662, filed on Mar. 10, 2025; the entire contents of which are incorporated herein by reference.

### FIELD

Embodiments of the invention relate to a chip-stacked device.

### BACKGROUND

A device in which two chips are stacked by metal-to-metal bonding is known.

### BRIEF DESCRIPTION OF THE DRAWINGS

FIG. 1 is a schematic plan view of a chip-stacked device according to a first embodiment;

FIG. 2A is a cross-sectional view taken along line A-A in FIG. 1;

FIG. 2B is a schematic cross-sectional view of a chip-stacked device according to a first modification of the first embodiment;

FIG. 3A is a schematic cross-sectional view of a chip-stacked device according to a second modification of the first embodiment;

FIG. 3B is a schematic cross-sectional view of a chip-stacked device according to a third modification of the first embodiment;

FIG. 4A is a schematic cross-sectional view of a chip-stacked device according to a fourth modification of the first embodiment;

FIG. 4B is a schematic cross-sectional view of a chip-stacked device according to a fifth modification of the first embodiment;

FIG. 5 is a schematic plan view of a chip-stacked device according to a second embodiment;

FIG. 6 is a cross-sectional view taken along line B-B in FIG. 5; and

FIG. 7 is a schematic cross-sectional view of a chip-stacked device according to a third embodiment.

### DETAILED DESCRIPTION

According to embodiments of the invention, a chip-stacked device includes: a first chip including a first substrate, the first substrate including a first outer peripheral region and a first array region surrounded by the first outer peripheral region; a second chip including a second substrate, the second substrate including a second outer peripheral region and a second array region, the second outer peripheral region facing the first outer peripheral region in a first direction, the second array region being surrounded by the second outer peripheral region and facing the first array region in the first direction; and a plurality of bonding members provided between the first array region and the second array region to bond the first chip and the second chip, a thickness of the second outer peripheral region of the second substrate in the first direction being thicker than a thickness of the second array region of the second substrate in the first direction.

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

### First Embodiment

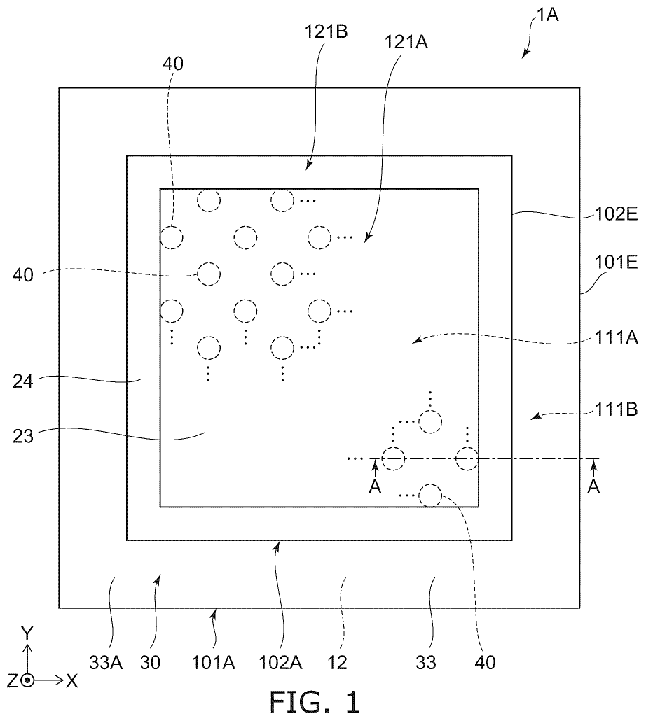

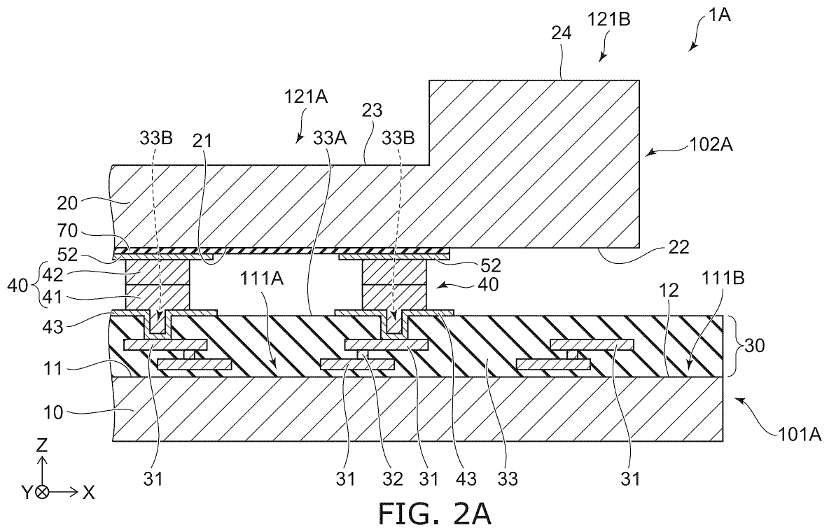

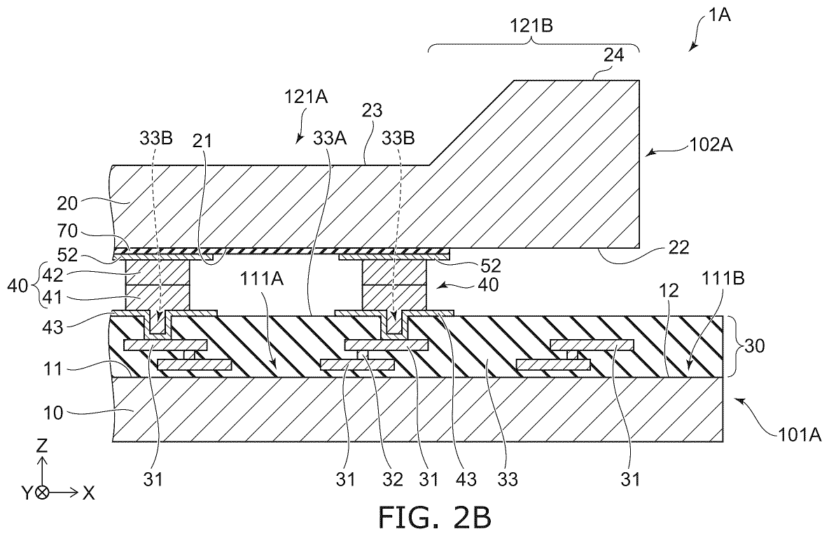

With reference to FIG. 1 and FIG. 2A, a chip-stacked device 1A according to a first embodiment will be described.

As shown in FIG. 2A, the chip-stacked device 1A includes a first chip 101A and a second chip 102A. The first chip 101A and the second chip 102A are stacked in a first direction Z. Two directions orthogonal to each other in a plane orthogonal to the first direction Z are defined as a second direction X and a third direction Y.

As shown in FIG. 1, for example, the planar size of the second chip 102A is smaller than the planar size of the first chip 101A, and an outer edge 102E of the second chip 102A is located inside an outer edge 101E of the first chip 101A in plan view.

As shown in FIG. 2A, the first chip 101A includes a first substrate 10 and an interconnect portion 30. The wiring portion 30 includes at least an interconnect layer 31 in one layer. This embodiment illustrates an example in which the interconnect portion 30 has a multilayer wiring structure including interconnect layers 31 in multiple layers.

The first substrate 10 is, for example, a silicon substrate. The first substrate 10 includes a first outer peripheral region 111B, and a first array region 111A located inside the first outer peripheral region 111B and surrounded by the first outer peripheral region 111B in plan view.

The first substrate 10 includes a first array surface 11 located in the first array region 111A and a first outer peripheral surface 12 located in the first outer peripheral region 111B. In plan view, the first array surface 11 is located inside the first outer peripheral surface 12 and is surrounded by the first outer peripheral surface 12.

The interconnect portion 30 is continuously provided on the first array surface 11 and on the first outer peripheral surface 12. The interconnect portion 30 includes the interconnect layer 31 and an insulating layer 33. The interconnect layer 31 is provided in the insulating layer 33. In a case where interconnect layers 31 in multiple layers are provided, the interconnect portion 30 further includes a conductive via 32 connecting the interconnect layers 31 in different layers to each other.

The first chip 101A can include semiconductor elements (a transistor, a diode, etc.) formed on the first substrate 10. The semiconductor elements are electrically connected to the interconnect layer 31.

The interconnect portion 30 can include a pad portion provided on a surface 33A of the insulating layer 33 in the first outer peripheral region 111B and connected to the interconnect layer 31. The pad portion is electrically connected to, for example, an external circuit via a wire. The interconnect layer 31 can be electrically connected to the external circuit via the pad portion and the wire. The pad portion can be provided in a region on the surface 33A of the insulating layer 33, the region not facing a second substrate 20. This allows wire bonding to the pad portion.

The first chip 101A further includes a first conductive film 43. The first conductive film 43 is provided on the surface 33A of the insulating layer 33, facing the second substrate 20. The insulating layer 33 includes an opening portion 33B reaching the interconnect layer 31 from the surface 33A. The first conductive film 43 is also provided in the opening portion 33B and is connected to the interconnect layer 31 in the opening portion 33B. As the material of the first conductive film 43, for example, TiN (titanium nitride) can be used.

The second chip 102A includes the second substrate 20. The second substrate 20 is, for example, a silicon substrate. The second substrate 20 includes a second outer peripheral region 121B, and a second array region 121A located inside the second outer peripheral region 121B and surrounded by the second outer peripheral region 121B in plan view.

The second substrate 20 includes a second array surface 21 located in the second array region 121A and a second outer peripheral surface 22 located in the second outer peripheral region 121B. In plan view, the second array surface 21 is located inside the second outer peripheral surface 22 and is surrounded by the second outer peripheral surface 22. The second array surface 21 faces the first array surface 11 of the first chip 101A in the first direction Z. The second outer peripheral surface 22 faces the first outer peripheral surface 12 of the first chip 101A in the first direction Z.

The interconnect portion 30 is continuously provided between the first array surface 11 and the second array surface 21, and between the first outer peripheral surface 12 and the second outer peripheral surface 22.

The second substrate 20 further includes a third array surface 23 located in the second array region 121A and a third outer peripheral surface 24 located in the second outer peripheral region 121B. In plan view, the third array surface 23 is located inside the third outer peripheral surface 24 and is surrounded by the third outer peripheral surface 24. The third array surface 23 is located on a side opposite to the second array surface 21 in the first direction Z. The third outer peripheral surface 24 is located on a side opposite to the second outer peripheral surface 22 in the first direction Z.

The thickness of the second outer peripheral region 121B of the second substrate 20 in the first direction Z is thicker than the thickness of the second array region 121A of the second substrate 20 in the first direction Z. In this specification, the thickness of the substrate in the first direction Z indicates the maximum thickness in the first direction Z. As shown in FIG. 2 A, a step is formed between the third array surface 23 and the third outer peripheral surface 24 of the second substrate 20. For example, the thickness of the second array region 121A in the first direction Z is not less than 100 μm and not more than 130 μm, and the thickness of the second outer peripheral region 121B in the first direction Z is 200 μm or more.

The thickness of the first array region 111A of the first substrate 10 in the first direction Z and the thickness of the first outer peripheral region 111B of the first substrate 10 in the first direction Z are the same and, for example, not less than 100 μm and not more than 130 μm.

The second chip 102A further includes a second conductive film 52. For example, the second conductive film 52 is provided on the second array surface 21 of the second substrate 20 with an insulating film 70 interposed therebetween. As the material of the second conductive film 52, for example, TiN can be used. On the second substrate 20, semiconductor elements electrically connected to the second conductive film 52 may be formed.

The chip-stacked device 1A according to the first embodiment further includes a plurality of bonding members 40 provided between the first array region 111A of the first substrate 10 and the second array region 121A of the second substrate 20. The plurality of bonding members 40 bond the first chip 101A and the second chip 102A.

As shown in FIG. 1, in plan view, the plurality of bonding members 40 are arranged in the second direction X and the third direction Y. No bonding member 40 is disposed in the first outer peripheral region 111B of the first substrate 10 and the second outer peripheral region 121B of the second substrate 20. The first outer peripheral region 111B of the first substrate 10 and the second outer peripheral region 121B of the second substrate 20 are located outside the outer edge of the outermost bonding member 40 of the plurality of bonding members 40 arranged in the first array region 111A and the second array region 121A.

The bonding member 40 is conductive. The bonding member 40 is formed by bonding a first metal portion 41 provided on the first chip 101A side and a second metal portion 42 provided on the second chip 102A side. The first metal portion 41 and the second metal portion 42 include, for example, Au (gold), and the bonding member 40 is an Au-to-Au bonded body. The boundary between the first metal portion 41 and the second metal portion 42 might not be clearly visible.

For example, the first metal portion 41 is electrically connected to the interconnect layer 31 via the first conductive film 43. The first metal portion 41 is connected to the first conductive film 43 on the surface 33A of the insulating layer 33. Further, a part of the first metal portion 41 is connected to the first conductive film 43 in the opening portion 33B. The second metal portion 42 is connected to the second conductive film 52 of the second chip 102A. The interconnect layer 31 of the first chip 101A is electrically connected to the second conductive film 52 of the second chip 102A via the first conductive film 43 and the bonding member 40.

The first metal portion 41 and the second metal portion 42 can be directly bonded to form the bonding member 40 by bringing the first metal portion 41 provided on the first chip 101A side and the second metal portion 42 provided on the second chip 102A side into contact with each other, applying a load to the first metal portion 41 and the second metal portion 42 in the first direction Z, and heating the first metal portion 41 and the second metal portion 42. In the process of bonding the first chip 101A and the second chip 102A via the bonding member 40, for example, the first chip 101A is placed relatively lower and supported on a supporting member, and the load described above is applied to the second chip 102A side.

When the first substrate 10 and the second substrate 20 are made thinner, the height of the chip-stacked device 1A in the first direction Z can be reduced. When the first substrate 10 and the second substrate 20 are made thinner, the mechanical strength of the substrates decreases and the substrates are likely to chip. For example, the first substrate 10 and the second substrate 20 are likely to chip upon, for example, handling of the first chip 101A and the second chip 102A. Upon the handling, the first outer peripheral region 111B of the first substrate 10 and the second outer peripheral region 121B of the second substrate 20 are sucked by a suction member, and therefore, the first outer peripheral region 111B and the second outer peripheral region 121B are likely to chip.

In the bonding process described above, the second substrate 20 of the second chip 102A to which the load is applied is likely to chip. Further, the second outer peripheral region 121B, which is not supported by the bonding member 40, is likely to chip.

For example, there is a possibility that a part of the outer edge of the second outer peripheral region 121B of the second substrate 20 chips, and a fragment of the second substrate 20 enters the gap between the second outer peripheral surface 22 of the second substrate 20 and the interconnect portion 30 of the first chip 101A. Then, when a load in the first direction Z is applied to the first chip 101A and the second chip 102A to bond the chips, the fragment entering the gap is caught between the second outer peripheral surface 22 and the interconnect portion 30, is pressed against the interconnect layer 31 located on the first outer peripheral surface 12 of the first substrate 10, and may cause damage to the interconnect layer 31.

According to this embodiment, since the thickness of the second outer peripheral region 121B of the second substrate 20 in the first direction Z is made thicker than the thickness of the second array region 121A of the second substrate 20 in the first direction Z, the mechanical strength of the second outer peripheral region 121B of the second substrate 20 can be increased. This improves the handleability of the second chip 102A, and can reduce chipping of the second outer peripheral region 121B of the second substrate 20. Since chipping of the second substrate 20 can be reduced, the reliability of the chip-stacked device 1A can be increased.

FIG. 2B is a schematic cross-sectional view of the chip-stacked device 1A according to a first modification of the first embodiment.

The third outer peripheral surface 24 of the second outer peripheral region 121B of the second substrate 20 may include a tilted surface that is tilted with respect to the first direction Z in a portion connected to the third array surface 23 of the second array region 121A.

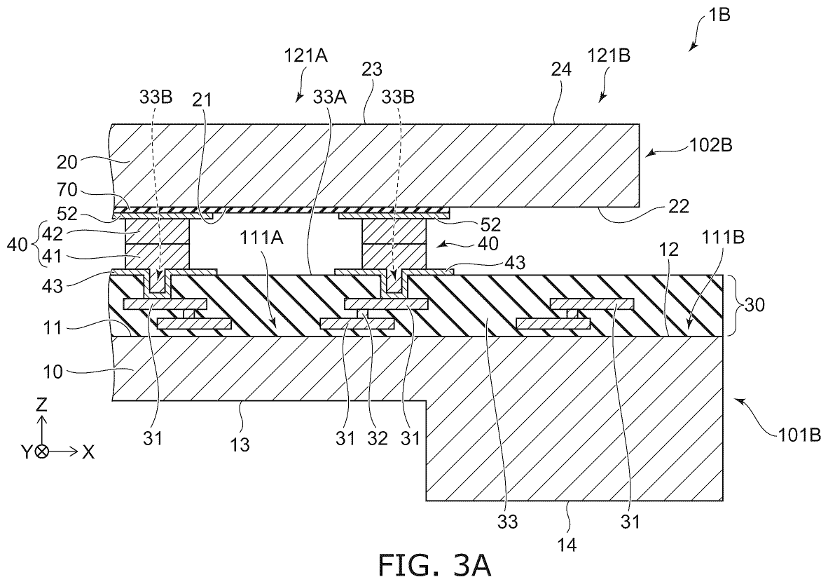

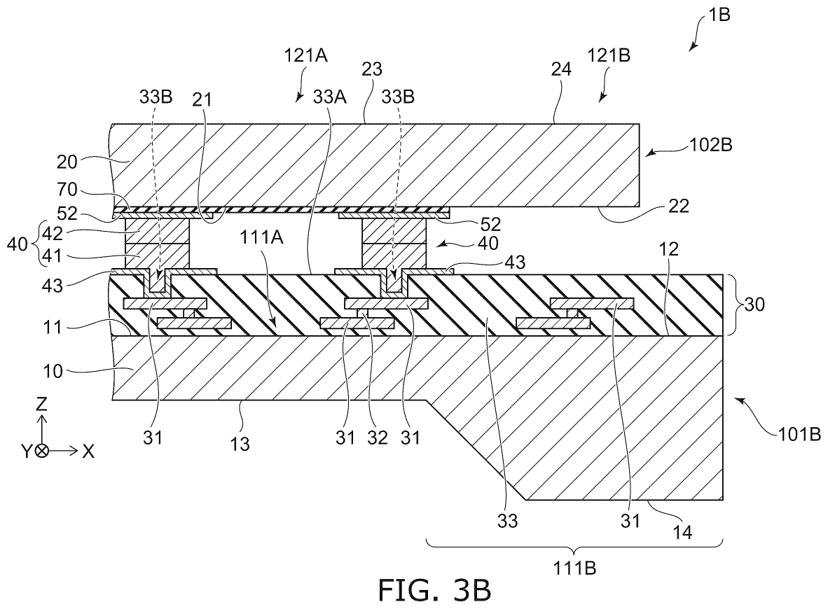

FIG. 3A is a schematic cross-sectional view of a chip-stacked device 1B according to a second modification of the first embodiment.

The chip-stacked device 1B according to the second modification includes a first chip 101B and a second chip 102B. The first chip 101B and the second chip 102B are bonded in the first direction Z via the plurality of bonding members 40.

The first chip 101B includes the first substrate 10. The first substrate 10 of the first chip 101B includes the first outer peripheral region 111B, and the first array region 111A located inside the first outer peripheral region 111B and surrounded by the first outer peripheral region 111B in plan view.

The first substrate 10 includes the first array surface 11 located in the first array region 111A and the first outer peripheral surface 12 located in the first outer peripheral region 111B.

The first substrate 10 according to the second modification further includes a fourth array surface 13 located in the first array region 111A and a fourth outer peripheral surface 14 located in the first outer peripheral region 111B. In plan view, the fourth array surface 13 is located inside the fourth outer peripheral surface 14 and is surrounded by the fourth outer peripheral surface 14. The fourth array surface 13 is located on a side opposite to the first array surface 11 in the first direction Z. The fourth outer peripheral surface 14 is located on a side opposite to the first outer peripheral surface 12 in the first direction Z.

In the second modification, the thickness of the first outer peripheral region 111B of the first substrate 10 in the first direction Z is thicker than the thickness of the first array region 111A of the first substrate 10 in the first direction Z. A step is formed between the fourth array surface 13 and the fourth outer peripheral surface 14 of the first substrate 10. For example, the thickness of the first array region 111A in the first direction Z is not less than 100 μm and not more than 130 μm, and the thickness of the first outer peripheral region 111B in the first direction Z is 200 μm or more.

Since the thickness of the first outer peripheral region 111B of the first substrate 10 in the first direction Z is made thicker than the thickness of the first array region 111A of the first substrate 10 in the first direction Z, the handleability of the first chip 101B is improved and chipping of the first outer peripheral region 111B of the first substrate 10 can be reduced.

The second chip 102B of the second modification includes the second substrate 20. The second substrate 20 of the second chip 102B includes the second outer peripheral region 121B, and the second array region 121A located inside the second outer peripheral region 121B and surrounded by the second outer peripheral region 121B in plan view.

In the second chip 102B, the thickness of the second array region 121A of the second substrate 20 in the first direction Z and the thickness of the second outer peripheral region 121B of the second substrate 20 in the first direction Z are the same and, for example, not less than 100 μm and not more than 130 μm.

FIG. 3B is a schematic cross-sectional view of the chip-stacked device 1B according to a third modification of the first embodiment.

The fourth outer peripheral surface 14 of the first outer peripheral region 111B of the first substrate 10 may include a tilted surface that is tilted with respect to the first direction Z in a portion connected to the fourth array surface 13 of the first array region 111A.

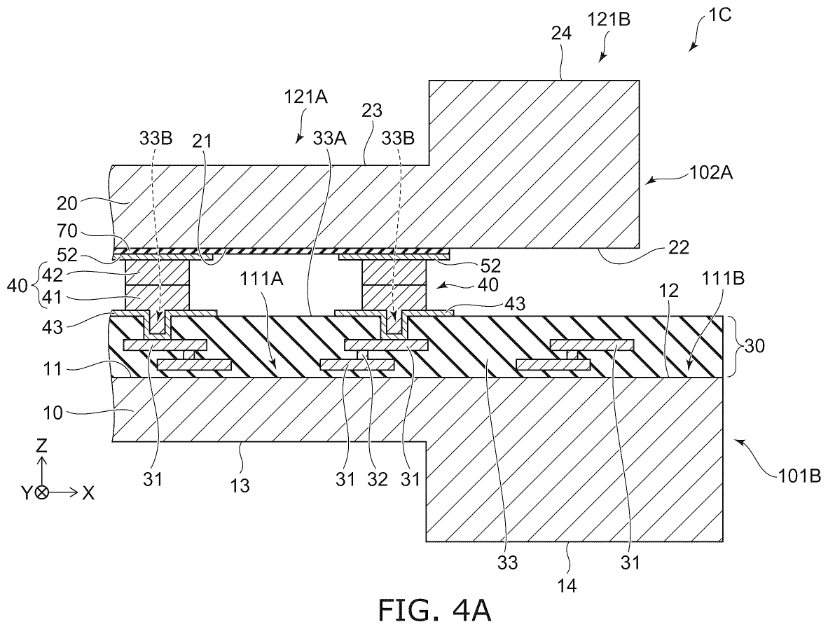

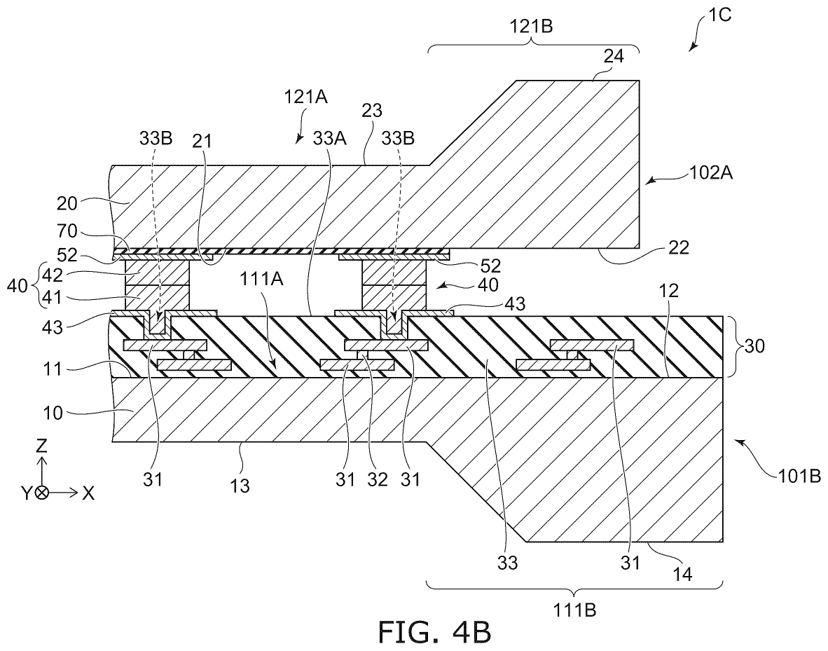

FIG. 4A is a schematic cross-sectional view of a chip-stacked device 1C according to a fourth modification of the first embodiment.

The chip-stacked device 1C according to the fourth modification includes the first chip 101B shown in FIG. 3A and the second chip 102A shown in FIG. 2A. The first chip 101B and the second chip 102A are bonded in the first direction Z via the plurality of bonding members 40.

In the fourth modification, since the thickness of the first outer peripheral region 111B of the first substrate 10 in the first direction Z is made thicker than the thickness of the first array region 111A of the first substrate 10 in the first direction Z, and the thickness of the second outer peripheral region 121B of the second substrate 20 in the first direction Z is made thicker than the thickness of the second array region 121A of the second substrate 20 in the first direction Z, the handleability of the first chip 101B and the second chip 102A is improved and chipping of the first outer peripheral region 111B of the first substrate 10 and the second outer peripheral region 121B of the second substrate 20 can be reduced.

FIG. 4B is a schematic cross-sectional view of the chip-stacked device 1C according to a fifth modification of the first embodiment.

The chip-stacked device 1C according to the fifth modification includes the first chip 101B shown in FIG. 3B and the second chip 102A shown in FIG. 2B.

### Second Embodiment

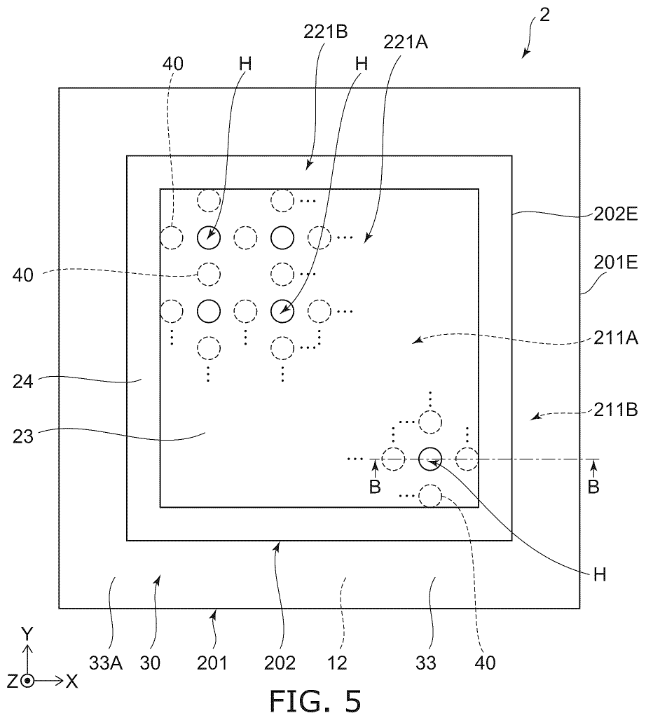

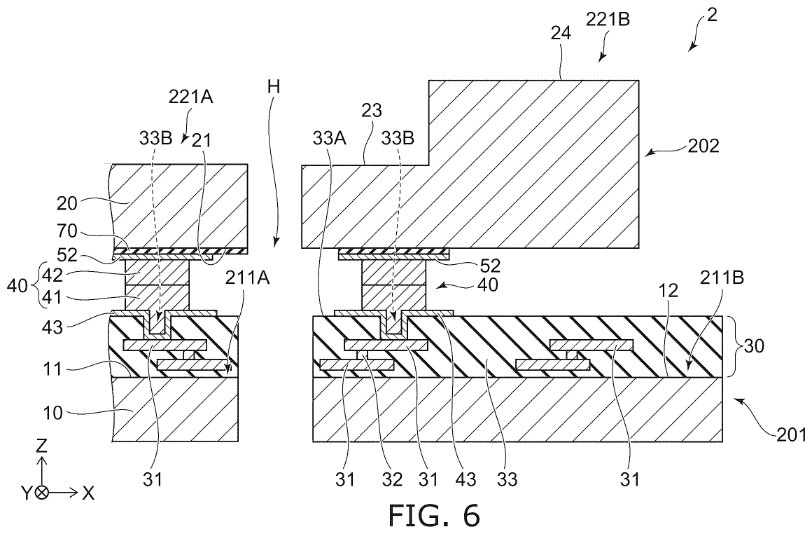

With reference to FIG. 5 and FIG. 6, a chip-stacked device 2 according to a second embodiment will be described.

The chip-stacked device 2 according to the second embodiment includes a first chip 201 and a second chip 202. The first chip 201 and the second chip 202 are bonded in the first direction Z via the plurality of bonding members 40.

As shown in FIG. 5, for example, the planar size of the second chip 202 is smaller than the planar size of the first chip 201, and an outer edge 202E of the second chip 202 is located inside an outer edge 201E of the first chip 201 in plan view.

The first chip 201 includes the first substrate 10. The first substrate 10 of the first chip 201 includes a first outer peripheral region 211B, and a first array region 211A located inside the first outer peripheral region 211B and surrounded by the first outer peripheral region 211B in plan view.

The first substrate 10 includes the first array surface 11 located in the first array region 211A and the first outer peripheral surface 12 located in the first outer peripheral region 211B.

The first chip 201 further includes the interconnect portion 30 and the first conductive film 43 as in the first embodiment.

The second chip 202 includes the second substrate 20. The second substrate 20 of the second chip 202 includes a second outer peripheral region 221B, and a second array region 221A located inside the second outer peripheral region 221B and surrounded by the second outer peripheral region 221B in plan view.

The second chip 202 further includes the second conductive film 52 as in the first embodiment.

The chip-stacked device 2 according to the second embodiment further includes a through hole H extending through the second array region 221A of the second substrate 20, the interconnect portion 30, and the first array region 211A of the first substrate 10 in the first direction Z. As shown in FIG. 5, a plurality of through holes H are arranged in the second direction X and the third direction Y. For example, the through hole H is located between the bonding members 40 adjacent to each other in the second direction X, and the through hole H is located between the bonding members 40 adjacent to each other in the third direction Y.

The plurality of through holes H are disposed in the first array region 211A and the second array region 221A, and no through hole H is disposed in the first outer peripheral region 211B and the second outer peripheral region 221B. In the chip-stacked device 2, the mechanical strength of the first chip 201 and the second chip 202 can be increased by the first outer peripheral region 211B and the second outer peripheral region 221B in which no through hole H is formed.

In the chip-stacked device 2 according to the second embodiment, the thickness of the second outer peripheral region 221B of the second substrate 20 in the first direction Z is thicker than the thickness of the second array region 221A of the second substrate 20 in the first direction Z. This improves the handleability of the second chip 202, and can reduce chipping of the second outer peripheral region 221B of the second substrate 20.

When the first array region 211A of the first substrate 10 and the second array region 221A of the second substrate 20 are made thinner, the aspect ratio (the ratio of the length in the first direction Z to the width or diameter) of the through holes formed in each of the first array region 211A and the second array region 221A can be reduced. This can facilitate the process of forming the through holes in each of the first array region 211A and the second array region 221A by, for example, etching.

The second embodiment may be combined with the first modification or the second modification described above.

### Third Embodiment

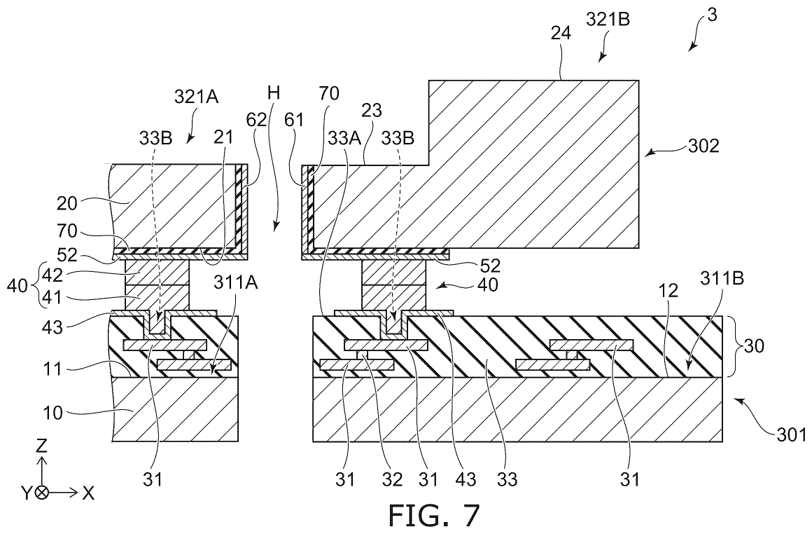

With reference to FIG. 7, a chip-stacked device 3 according to a third embodiment will be described.

The chip-stacked device 3 according to the third embodiment includes a first chip 301 and a second chip 302. The first chip 301 and the second chip 302 are bonded in the first direction Z via the plurality of bonding members 40.

The first chip 301 includes the first substrate 10. The first substrate 10 of the first chip 301 includes a first outer peripheral region 311B, and a first array region 311A located inside the first outer peripheral region 311B and surrounded by the first outer peripheral region 311B in plan view.

The first substrate 10 includes the first array surface 11 located in the first array region 311A and the first outer peripheral surface 12 located in the first outer peripheral region 311B.

The first chip 301 further includes the interconnect portion 30 and the first conductive film 43 as in the first embodiment.

The second chip 302 includes the second substrate 20. The second substrate 20 of the second chip 302 includes a second outer peripheral region 321B, and a second array region 321A located inside the second outer peripheral region 321B and surrounded by the second outer peripheral region 321B in plan view.

The second chip 302 further includes the second conductive film 52 as in the first embodiment.

The chip-stacked device 3 according to the third embodiment further includes the through hole H extending through the second array region 321A of the second substrate 20, the interconnect portion 30, and the first array region 311A of the first substrate 10 in the first direction Z, as in the second embodiment.

In the chip-stacked device 3 according to the third embodiment, the second chip 302 further includes an electrode provided on the inner wall of the through hole H and electrically connected to the bonding member 40. The electrode can include a first electrode 61 and a second electrode 62.

The first electrode 61 is provided on the inner wall of the through hole H with the insulating film 70 interposed therebetween, and is electrically connected to the second conductive film 52 provided on the second array surface 21. The second electrode 62 is provided on the inner wall of the through hole H with the insulating film 70 interposed therebetween, at a position facing the first electrode 61, and is electrically connected to the second conductive film 52 provided on the second array surface 21. The second conductive film 52 connected to the first electrode 61 and the second conductive film 52 connected to the second electrode 62 are separated from each other on the insulating film 70.

A first system in which the interconnect layer 31 and the first electrode 61 are electrically connected via the first conductive film 43, the bonding member 40, and the second conductive film 52, and a second system in which the interconnect layer 31 and the second electrode 62 are electrically connected via the first conductive film 43, the bonding member 40, and the second conductive film 52 can be controlled independently of each other. To the first electrode 61 and the second electrode 62, different potentials can be applied. For example, an electric field can be generated in the through hole H by applying a positive potential to the first system and applying a ground potential to the second system. The electric field generated in the through hole H can deflect a charged particle beam, such as an electron beam, passing through the through hole H.

In the chip-stacked device 3 according to the third embodiment, the thickness of the second outer peripheral region 321B of the second substrate 20 in the first direction Z is thicker than the thickness of the second array region 321A of the second substrate 20 in the first direction Z. This improves the handleability of the second chip 302, and can reduce chipping of the second outer peripheral region 321B of the second substrate 20.

The third embodiment may be combined with the first modification or the second modification described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A chip-stacked device comprising:
a first chip including a first substrate, the first substrate including a first outer peripheral region and a first array region surrounded by the first outer peripheral region;
a second chip including a second substrate, the second substrate including a second outer peripheral region and a second array region, the second outer peripheral region facing the first outer peripheral region in a first direction, the second array region being surrounded by the second outer peripheral region and facing the first array region in the first direction; and
a plurality of bonding members provided between the first array region and the second array region to bond the first chip and the second chip,
a thickness of the second outer peripheral region of the second substrate in the first direction being thicker than a thickness of the second array region of the second substrate in the first direction.

2. The chip-stacked device according to claim 1, wherein a thickness of the first outer peripheral region of the first substrate in the first direction is thicker than a thickness of the first array region of the first substrate in the first direction.

3. The chip-stacked device according to claim 1, further comprising: a through hole extending through the second array region of the second substrate and the first array region of the first substrate in the first direction.

4. The chip-stacked device according to claim 3, wherein the second chip further includes an electrode provided on an inner wall of the through hole and electrically connected to the bonding member.

5. The chip-stacked device according to claim 4, wherein
the first chip further includes an interconnect portion provided between the first substrate and the second substrate, and
the interconnect portion includes a interconnect layer electrically connected to the electrode via the bonding member.

6. A chip-stacked device comprising:
a first chip including a first substrate, the first substrate including a first outer peripheral region and a first array region surrounded by the first outer peripheral region;
a second chip including a second substrate, the second substrate including a second outer peripheral region and a second array region, the second outer peripheral region facing the first outer peripheral region in a first direction, the second array region being surrounded by the second outer peripheral region and facing the first array region in the first direction; and
a plurality of bonding members provided between the first array region and the second array region to bond the first chip and the second chip,
a thickness of the first outer peripheral region of the first substrate in the first direction being thicker than a thickness of the first array region of the first substrate in the first direction.

7. The chip-stacked device according to claim 6, further comprising: a through hole extending through the second array region of the second substrate and the first array region of the first substrate in the first direction.

8. The chip-stacked device according to claim 7, wherein the second chip further includes an electrode provided on an inner wall of the through hole and electrically connected to the bonding member.

9. The chip-stacked device according to claim 8, wherein
the first chip further includes an interconnect portion provided between the first substrate and the second substrate, and
the interconnect portion includes an interconnect layer electrically connected to the electrode via the bonding member.
